(19) United States
(12) Patent Application Publication
(10) Pub. No.: US 2026/0277206 A1
(43) Pub. Date: Sep. 17, 2026

(54) CONTINUOUS CAPTURE OF ELECTRICAL SIGNATURES WITH IOT ENABLED MONITORS

(71) Applicant: Volta Insite (US) Inc., Cornelius, NC (US)

(72) Inventors: Karl Lindstrom, Sunnyvale, CA (US); Denis Kouroussis, Markham (CA); Daniel Montbriand, Santa Cruz, CA (US); Karimulla Raja Shaikh, Cupertino, CA (US); Jaspreet Singh, Brampton (CA)

(73) Assignee: Volta Insite (US) Inc., Cornelius, NC (US)

(21) Appl. No.: 19/565,654

(22) Filed: Mar. 13, 2026

Related U.S. Application Data
(60) Provisional application No. 63/771,714, filed on Mar. 14, 2025.
(60) Provisional application No. 63/779,393, filed on Mar. 28, 2025.
(60) Provisional application No. 63/787,764, filed on Apr. 12, 2025.
(60) Provisional application No. 63/814,170, filed on May 29, 2025.
(60) Provisional application No. 63/824,111, filed on Jun. 15, 2025.
(60) Provisional application No. 63/842,417, filed on Jul. 11, 2025.
(60) Provisional application No. 63/868,054, filed on Aug. 21, 2025.
(60) Provisional application No. 63/875,633, filed on Sep. 4, 2025.
(60) Provisional application No. 63/886,244, filed on Sep. 23, 2025.
(60) Provisional application No. 63/893,080, filed on Oct. 3, 2025.
(60) Provisional application No. 63/908,902, filed on Oct. 31, 2025.
(60) Provisional application No. 63/920,989, filed on Nov. 19, 2025.
(60) Provisional application No. 63/920,997, filed on Nov. 19, 2025.
(60) Provisional application No. 63/927,701, filed on Nov. 30, 2025.
(60) Provisional application No. 63/933,557, filed on Dec. 8, 2025.
(60) Provisional application No. 63/951,992, filed on Dec. 31, 2025.
(60) Provisional application No. 63/969,898, filed on Jan. 28, 2026.
(60) Provisional application No. 63/980,195, filed on Feb. 11, 2026.
(60) Provisional application No. 63/980,279, filed on Feb. 11, 2026.
(60) Provisional application No. 63/991,428, filed on Feb. 26, 2026.

(51) Int. Cl. G05B 23/02; G01R 19/165

(52) U.S. Cl. CPC G05B 23/024; G01R 19/16528

(57) ABSTRACT

An industrial IoT electrical monitor (IIEM) is accessed. The IIEM is coupled to one or more industrial devices within one or more environments. The IIEM receives, from a cloud server, one or more uploading instructions. Electrical data associated with the one or more industrial devices is recorded by the IIEM. The IIEM determines whether the electrical data that was recorded represents a situation of interest related to the one or more industrial devices. The determining is based on the one or more uploading instructions. The IIEM uploads the electrical data to the cloud server. The uploading is based on the determining. The one or more uploading instructions include an uploading frequency. The uploading is based on the uploading frequency. The IIEM performs local analysis on the electrical data that was recorded. The performing is based on the uploading frequency and includes the local analysis.

### RELATED APPLICATIONS

This application claims the benefit of U.S. provisional patent applications “Continuous Capture Of Electrical Signatures With IOT Enabled Monitors” Ser. No. 63/771,714, filed Mar. 14, 2025, “Autonomous Identification Of Electrical Signatures With IOT-Enabled Monitors” Ser. No. 63/779,393, filed Mar. 28, 2025, “Identification Of Electrical Signatures With Local Machine Learning Models On An IOT-Enabled Monitor” Ser. No. 63/787,764, filed Apr. 12, 2025, “Ground Fault Identification With IOT Enabled Monitors” Ser. No. 63/814,170, filed May 29, 2025, “Detection And Response To Frequency Deviations With IOT Enabled Monitors” Ser. No. 63/824,111, filed Jun. 15, 2025, “Frequency Deviation Detection And Response With IOT-Enabled Monitors” Ser. No. 63/842,417, filed Jul. 11, 2025, “Industrial Device Root Cause Analysis With Artificial Intelligence Agents” Ser. No. 63/868,054, filed Aug. 21, 2025, “Root Cause Analysis On Industrial Devices With Artificial Intelligence Agents” Ser. No. 63/875,633, filed Sep. 4, 2025, “Contactor Monitoring And Analysis With IOT-Enabled Monitors” Ser. No. 63/886,244, filed Sep. 23, 2025, “Variable Frequency Drive Isolation With IOT-Enabled Monitors” Ser. No. 63/893,080, filed Oct. 3, 2025, “Reconstruction Of Saturated Electrical Data With Industrial IOT Electrical Monitors” Ser. No. 63/908,902, filed Oct. 31, 2025, “Aggregated Analysis Of Electrical Signatures With Event Filters And Industrial IOT-Enabled Monitors” Ser. No. 63/920,989, filed Nov. 19, 2025, “Self-Regulating Industrial IOT-Enabled Monitors (IIEMS) With Event Filters” Ser. No. 63/920,997, filed Nov. 19, 2025, “Monitoring Variable Resolution Electrical Data With Industrial IOT Electrical Monitors” Ser. No. 63/927,701, filed Nov. 30, 2025, “Isolation For Electrical Analysis Of Industrial Equipment With Industrial IOT-Enabled Monitors” Ser. No. 63/933,557, filed Dec. 8, 2025, “Managing Anomalous Events Associated With Industrial Devices With An Applications Engineer Artificial Intelligence Agent” Ser. No. 63/951,992, filed Dec. 31, 2025, “Automatic Initialization Of Industrial IOT-Enabled Monitors” Ser. No. 63/969,898, filed Jan. 28, 2026, “Initializing Industrial IOT-Enabled Monitors With Zero Crossing Time Lags” Ser. No. 63/980,195, filed Feb. 11, 2026, “Residual Back EMF Analysis With Industrial IOT-Enabled Monitors Coupled To Industrial Devices” Ser. No. 63/980,279, filed Feb. 11, 2026, “Recognizing Anomalous Events With Frequency Transformations By IOT-Enabled Monitors” Ser. No. 63/991,428, filed Feb. 26, 2026, “Internal Temperature Tracking Of Industrial Devices With IOT-Enabled Monitors” Ser. No. 63/991,451, filed Feb. 26, 2026, and “Auto Channel Mapping For IOT-Enabled Monitors Coupled To Industrial Devices” Ser. No. 63/994,200, filed Mar. 2, 2026.

Each of the foregoing applications is hereby incorporated by reference in its entirety.

### FIELD OF ART

This application relates generally to equipment monitoring, and more particularly to continuous capture of electrical signals with IoT-enabled monitors.

### BACKGROUND

Industrial equipment provides essential utilities, such as electricity, natural gas, and water, for a modern economy. Examples of industrial equipment can include turbines, transformers, and generators that contribute to a stable electrical grid. Natural gas equipment can include compressors and metering systems that facilitate safe and efficient gas distribution. Similarly, efficient water distribution relies on pumps, filtration systems, and metering systems to deliver clean water to residential and business customers.

Manufacturing and distribution operations also rely on industrial equipment. Distribution relies on conveyor belts, elevators, and automated storage systems to efficiently ship and receive inventory. Manufacturers often utilize devices such as robotic arms, fans, elevators, ovens, centrifuges, and many other types of equipment to manufacture and/or package products. Robotic arms are used in assembly lines, performing tasks such as welding, painting, and material handling. These robotic arms serve to improve speed, accuracy, and safety while also reducing human labor costs. Industrial fans and ventilation systems perform important functions of maintaining airflow and temperature control in factories, and can also help to remove hazardous fumes, dust, and excess heat. Industrial ovens and furnaces are often used for drying, baking, and curing materials, and are widely employed in industries and applications such as food production, ceramics, metal forging, and pharmaceuticals. CNC (Computer Numerical Control) machines can automate the cutting, drilling, and shaping of metal, plastic, and wood. Further, these machines can enable precision manufacturing and ensure consistent quality. Centrifuges and separators are used for separating liquids and solids in various industries and are widely used in industries such as chemical processing, pharmaceuticals, and food production. Packaging machines automate tasks such as bottling, labeling, sealing, and wrapping. These packaging machines improve speed and sanitation, as well as reduce labor costs and ensure consistent packaging quality.

Data centers can be another example of industrial equipment, providing infrastructure that powers modern industries, enables economic growth, and fuels global commerce. From manufacturing and logistics to finance and e-commerce, nearly every sector relies on data centers for efficient operations and scalability. Businesses leverage data centers for cloud computing, AI, and big data analytics to improve efficiency. Online marketplaces, banking, and stock markets rely on secure, high-speed data processing. Governments, healthcare, and emergency services depend on data centers for real-time operations and secure data storage. These and many other important functions are enabled by efficient data centers. Various components, such as servers, load balancers, power supplies, and dedicated HVAC systems, all play a role in maintaining the proper operation of data centers.

Industrial equipment is essential for the economy to function, enabling businesses to produce goods and services faster, safer, and with greater precision. Further, industrial equipment can help companies scale production, reduce costs, and maintain high-quality standards. Without industrial equipment, modern civilization as we know them would not exist.

### SUMMARY

Industrial equipment failure can have severe consequences in both production and supply chains. When a critical machine malfunctions, production lines can come to a halt, impacting productivity, delivery schedules, and so on. Failures of industrial equipment can result in wasted inventory, especially in industries like food processing or chemical manufacturing where raw materials may spoil or become unusable. Ultimately, downtime can result in lost revenue as companies are unable to fulfill customer orders on time. Equipment failures can have a downstream effect, disrupting supply chains, causing shortages of essential goods, and affecting other businesses that rely on timely deliveries. In worst-case scenarios, prolonged failures can damage a company's reputation, lead to contract breaches, and even result in safety hazards. Regular maintenance, predictive analytics, and IoT-based monitoring systems can be used to minimize these risks and ensure operational continuity.

Disclosed embodiments provide techniques for equipment monitoring. An industrial IoT electrical monitor (IIEM) is accessed. The HEM is coupled to one or more industrial devices within one or more environments. The HEM receives one or more uploading instructions from a cloud server. Electrical data associated with one or more industrial devices is recorded by the IIEM. The IIEM determines whether the electrical data that was recorded represents a situation of interest which is related to the one or more industrial devices. The determining is based on the one or more uploading instructions. The IIEM uploads the electrical data to a cloud server, based on the determining.

A computer-implemented method for analysis is disclosed comprising: accessing an industrial IoT electrical monitor (IIEM), wherein the IIEM is coupled to one or more industrial devices within one or more environments, and wherein the HEM receives, from a cloud server, one or more uploading instructions; recording, by the IIEM, electrical data associated with the one or more industrial devices; determining, by the IIEM, whether the electrical data that was recorded represents a situation of interest related to the one or more industrial devices, wherein the determining is based on the one or more uploading instructions; and uploading, by the IIEM, to the cloud server, the electrical data, wherein the uploading is based on the determining. In embodiments, the one or more uploading instructions include an uploading frequency. In embodiments, the uploading is based on the uploading frequency. Some embodiments comprise performing local analysis, by the IIEM, on the electrical data that was recorded, wherein the performing is based on the uploading frequency, and wherein the uploading includes the local analysis. In embodiments, the determining includes calculating, by the IIEM, a deviation from normal operating conditions of the electrical data. In embodiments, the situation of interest comprises a difference between the deviation and a historical average, wherein the difference is above a threshold.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for continuous capture of electrical signatures with IoT-enabled monitors.

FIG. 2 is a flow diagram for determining a situation of interest.

FIG. 3 is an infographic for IoT environments.

FIG. 4 is a block diagram for continuous capture of electrical signatures with IoT-enabled monitors.

FIG. 5 is an example of a voltage transient.

FIG. 6 is an example of a phase drop.

FIG. 7 is a block diagram of an IIEM.

FIG. 8 is a system diagram for continuous capture of electrical signatures with IoT-enabled monitors.

### DETAILED DESCRIPTION

It is not an understatement to say that the world relies on industrial equipment. Every aspect of the world's economy relies on such equipment for providing power, refrigeration, maintenance, transportation, power, data services, and so on. Equipment failures, unscheduled maintenance stoppages, intermittent operation, etc. can have a significant impact on production and profit. However, it is not always easy to identify when a particular machine will fail. Machines can include many different components such as fans, belts, chillers, blowers, gears, arms, and so on, and any these elements can fail at any time, causing unscheduled downtime. Further, industrial environments such as manufacturing floors, food processing plants, data centers, and so on can have other issues that affect equipment. For example, power delivered to a piece of equipment may include transients which can cause failures to certain internal elements sensitive to power fluctuations. Variations in voltage, current, temperature, vibration, humidity, etc. can all affect equipment uptime. Predicting failures in light of these kinds of variations can be notoriously difficult. As a result, regular maintenance intervals can be scheduled for inspection, testing, etc. Because of the difficulty of predicting failure, downtime scheduling can be conservative, resulting in loss of production. But even the most conservative maintenance schedule cannot prevent failure caused by environmental factors such as those described above.

Disclosed implementations utilize an Industrial Internet of Things (IoT) Electrical Monitor (IIEM) to enable a smart, adaptive approach to monitoring industrial equipment, improving uptime, efficiency, reliability, and cost. Internet of Things (IoT) refers to a network of interconnected devices embedded with sensors, software, and/or communication technologies that collect and exchange data over the Internet. The HEM can enable continuous capture of electrical signatures with IoT-enabled monitors and can upload electrical data to a cloud server based on upload instructions provided by the cloud server. The IIEM can provide real-time alerts for potential failures, unusual power consumption, operational inefficiencies, and so on, enabling intelligent real-time monitoring, automation, and data-driven decision-making across various industries. In industrial settings, disclosed implementations can play a crucial role in optimizing operations, improving efficiency, and reducing downtime by providing improved access to, and analysis of, industrial device performance data.

Disclosed implementations that utilize IoT sensors can monitor power supply conditions, power consumption, temperature, vibrations, system efficiency, and/or other parameters. Disclosed implementations can serve to prevent equipment failures by detecting anomalies in power usage or overheating, triggering maintenance alerts and/or automated shutdown of equipment before a failure occurs. Additionally, disclosed implementations can help to optimize energy efficiency by identifying energy-wasting equipment or practices and provide insights for cost-saving adjustments. Moreover, disclosed implementations can serve to improve safety and compliance by ensuring that industrial devices operate within safe power limits to prevent electrical hazards.

Uploading instructions provided by a cloud server can dynamically control data upload rates. Thus, instead of continuously transmitting large amounts of data, disclosed implementations can adjust the upload rate based on operational and/or environmental conditions. This reduces unnecessary network bandwidth usage and minimizes the strain on processing power, making it ideal for environments with limited connectivity or high data costs. When normal conditions are detected, data transmission rates can slow down, reducing overhead while still maintaining essential monitoring. Furthermore, by optimizing the frequency of data uploads, disclosed implementations can help organizations reduce energy consumption associated with constant data processing, resulting in lower operating costs. Additionally, the cloud-based architecture enables organizations to monitor multiple IIEMs across different locations, ensuring centralized and scalable monitoring.

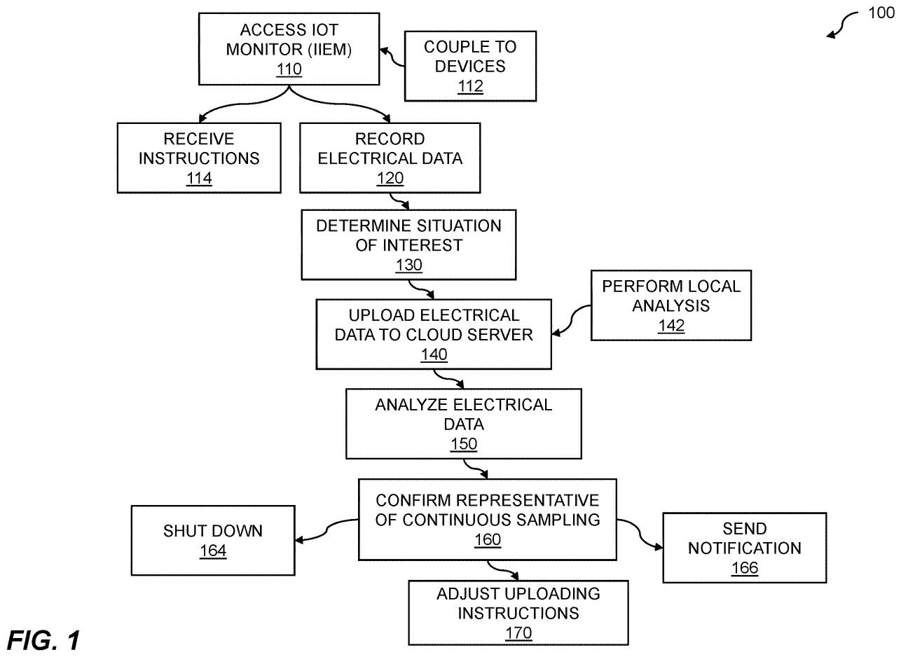

FIG. 1 is a flow diagram for continuous capture of electrical signatures with IoT-enabled monitors. The flow 100 can include accessing an industrial IoT electrical monitor (IIEM) 110, wherein the IIEM is coupled to one or more industrial devices 112 within one or more environments, and wherein the HEM receives, from a cloud server, one or more uploading instructions 114. The IIEM can comprise an IoT node which can interconnect devices, sensors, and servers to collect and exchange information over the Internet. In some implementations, the IIEM can be distinct from the IoT node. In those cases, one or more IIEMs within an environment can be coupled to one or more industrial devices. The one or more IIEMs can send data to the IoT device which can coordinate sending and receiving data with a server, cloud server, etc.

The IIEM can include one or more communication transceivers. The communication transceivers can be based on BLE (Bluetooth Low Energy); Wi-Fi; cellular communication protocols such as 4G, 5G, and LTE-M; and/or other suitable communication protocols. The transceivers can enable high-speed data transfer to cloud servers and/or local networks. Other communication transceivers can include LoRa (Long Range) and/or Zigbee communication receivers.

The IIEM can include a power source. The power source can include a battery, such as a rechargeable battery. In disclosed implementations, the battery can include a lithium-ion battery, lithium-ion polymer battery, and/or other suitable type of battery. In some cases, one or more IIEMs may include PoE (power over ethernet) to enable providing both power and network connectivity via a single cable. Some IIEMs may include energy harvesting features, such as solar cells, vibration-based energy generation, and/or other renewable energy sources that can enable remote, self-sustaining IoT monitoring.

The IIEM can include one or more processors. The processors can include an ARM®-based processor, a MIPS®-based processor, a custom processor, application specific integrated circuits (ASICS), systems-on-chip (SoCs), one or more embedded controllers, a processor within a Rasberry Pi® board, and/or another suitable processor or computer type. The IIEM can include one or more machine learning accelerators to enhance machine learning operations. The processors can serve to read sensor data, process interrupts, perform communication tasks, and/or execute other processes to accomplish IoT-based industrial device monitoring. The processor(s) can interface with an input/output (I/O) module. The I/O module can include analog inputs to enable reading signals from analog sensors such as temperature probes, current meters, voltage meters, and so on. The I/O module can include one or more analog-to-digital converters (ADCs) to convert analog signal levels into digital values. The I/O module can include digital inputs and outputs, such as GPIO (General Purpose I/O), in order to interface with other types of sensors such as tilt sensors, gyroscopes, accelerometers, and/or other types of sensors that provide digital outputs. Additionally, the I/O module can interface with an output device, such as an LED, buzzer, or other suitable output device. The I/O module can interface to a wide variety of sensors. The sensors can include temperature and humidity sensors to monitor environmental conditions. The sensors can include vibration sensors which can be used to detect mechanical wear and/or anomalies in industrial equipment. The sensors can include current sensors and voltage sensors, which can measure power consumption and/or detect electrical issues. Other types of sensors can be used in disclosed implementations.

The IEM can include computer storage, such as flash memory, for storing firmware images, configuration settings, and/or sensor logs. Additionally, some IIEMs can include an external storage interface, such as a microSD card slot, to enable local retrieval of collected data and/or logs. The computer storage can also include random-access memory (RAM) for supporting program execution and in some cases, analysis and/or processing of collected data.

The ITEM 110 is coupled to one or more industrial devices 112 within one or more environments. The coupling can include establishing a network connection between an IIEM and the one or more industrial devices. The network connection can be a wireless connection, such as via BLE, Wi-Fi, or other suitable connection. The network connection can be a wired connection, such as an ethernet connection, serial connection (e.g., RS-232, RS-485, or the like), and/or other type of wired connection. The coupling can include access, by the HEM, to internal nodes of the industrial equipment to monitor internal conditions. The coupling can include access to current and/or voltage entering or exiting the industrial device. The one or more industrial devices can include robotic arms, CNC machines, 3D printers, welding machines, injection molding machines, conveyor belts, packaging equipment, sorting machines, uninterruptible power supplies, generators, power transformers, industrial circuit breakers, power distribution units, industrial HVAC systems, furnaces, boilers, refrigeration units, dehumidifiers and humidifiers, pumps, compressors, mixing tanks, water treatment systems, data center computer servers, network switches, routers, and/or other types of industrial devices. Any type of equipment that requires electricity can be monitored by the IIEM.

A single IIEM can be coupled to a single device or multiple devices, providing efficient IoT monitoring. The equipment can be physically located in an environment. Any environment can be monitored by the IIEM. For example, the equipment can be located in a room within a food processing facility, a rack within a data center, a floor within a manufacturing facility, and so on. Any number of IIEMs can be coupled to any number of industrial devices in any number of environments. In a usage example, a single IIEM can be coupled to a bandsaw and a table saw within a wood shop.

The IIEM receives, from a cloud server, one or more uploading instructions 114. A cloud server can include a server in a cloud service such as Amazon Web Services (AWS), a custom managed server, a local server (e.g., on-site server, computer, and so on), etc. The cloud server can include any number of physical servers within a rack, data center, network, and so on. The cloud server can include any type of processor, ASIC, SoC, AI accelerator, etc. The uploading instructions can control how and when the HEM sends data once collected. In embodiments, the one or more uploading instructions include an uploading frequency, wherein the uploading is based on the uploading frequency. A default upload frequency can be established, allowing the HEM to upload data to the cloud server at a predefined frequency under normal operating conditions. The upload frequency can comprise any frequency such as ten times per hour, ten times per minute, and so on. In a usage example, the uploading instructions can cause an IIEM coupled to a bandsaw to send summarized data to the cloud server in ten minute increments. The uploading instructions can be heuristically developed. The instructions can be based on a historical database of equipment failures and/or electrical monitoring. A machine learning model, such as a large language model (LLM), neural network, transformer, and so on, can be used to determine appropriate instructions based on analysis of the historical database or other data. Thus, disclosed implementations can provide an industrial monitoring system that optimizes data transmission by dynamically adjusting the upload frequency based on real-time conditions.

The cloud server can modify the upload frequency based on predefined rules triggered by abnormal conditions, such as a condition of interest (explained below). In a usage example, the uploading instructions can be based on power anomalies. For example, an uploading instruction can specify that if voltage fluctuations exceed a certain threshold within a time window (e.g., more than ten fluctuations of 55% in ten minutes), then the upload frequency should be increased to every second for rapid diagnostics. Another example of an uploading instruction based on a power anomaly can specify that if one phase of a three-phase system is lost, the data upload rate should be increased so as to immediately report the issue and aid in rapid fault detection.

Uploading instructions can also be directed to environmental conditions. As an example, the uploading instructions can specify that if equipment temperature rises above a safe limit (for example, a percent increase, such as a 15% increase, over normal operating temperature), then the IIEM should upload data more frequently to monitor overheating risks. As another example, if humidity and/or air quality in a factory deviates beyond set limits, uploading frequency can be increased to analyze potential impacts on sensitive equipment. As another example, the uploading instructions can specify that if industrial equipment such as an industrial motor, robotic arm, or turbine experiences excessive vibration for an extended period of time, the uploading frequency should be adjusted to provide more granular insight into a potential failure. Uploading instructions can be directed to network conditions. As an example, an instruction can specify that upload frequency is reduced if network congestion is detected. This prevents system overload while still capturing critical data. These are non-limiting examples, and other rules may be used for monitoring industrial devices. In disclosed implementations, the rules can be provided by a user, such as a system administrator, system architect, etc. The uploading instructions can cause the IIEM to perform functions on the data that is collected prior to uploading. For example, the uploading instructions can cause the IIEM to perform a fast Fourier transform (FFT) on an electrical signal captured prior to sending data to the cloud server.

A cloud server can maintain one or more uploading instructions for one or more IIEMs coupled to one or more industrial devices. The IIEMs can receive the same or different uploading instructions from the cloud server. The uploading instructions can cause each IIEM to upload data on the same or different schedules, handle the same or different electrical data as a situation of interest, and so on. In embodiments, a first uploading instruction within the one or more uploading instructions is associated with a first industrial device within the one or more industrial devices, and a second uploading instruction within the one or more uploading instructions is associated with a second industrial device within the one or more industrial devices. In embodiments, an uploading frequency of the first uploading instruction is different from an uploading frequency of the second uploading instruction. In some implementations, each IIEM can accept different uploading instructions for different coupled equipment. In a usage example, an IIEM can track multiple pieces of equipment. A first piece of equipment can be waiting for a maintenance fix. Thus, uploading instructions associated with the first piece of equipment can be uploaded more frequently than another piece of equipment monitored by the same IIEM. Once the maintenance is performed, the uploading frequency associated with the uploading instructions for the first piece of equipment can be reset to the same frequency as other equipment monitored by the IIEM.

The flow 100 includes recording electrical data 120 associated with the one or more industrial devices. The one or more industrial devices can be operated with power such as AC power, three-phase power, DC power, etc. The HEM can record electrical data associated with signals, phases, etc. affiliated with such power as is provided. The IIEM can monitor power anywhere along the path of delivery to the industrial device. For example, a utility can provide three-phase power to the industrial environment. The IIEM can monitor each phase of this power input. Before powering the industrial device, the power can run through another device such as a contactor, a variable frequency drive (VFD), etc. The IIEM can monitor power both at the input and output of the contactor, VFD, or any other equipment or node as it is delivered to the industrial device. The IIEM can further monitor power, such as each phase of the three-phase power, at the input of the industrial device. Further, in an industrial environment, it is common for equipment to be manipulated by controllers such as a programmable logic controller (PLC). The IIEM can additionally monitor inputs and outputs of these control devices and compare control states with power delivery. This comprehensive monitoring provides unique insights into power delivery, control signaling, anomalous events, domain knowledge, and so on that can be used to identify, debug, etc. electrical anomalies associated with the industrial devices.

The electrical data can include average current, current spikes, average voltage, voltage spikes, frequency fluctuations, phase loss, power interruptions, voltage and/or current transients, voltage waveforms, current waveforms, and so on. The electrical data can include a power factor (PF) that measures how efficiently electrical power is being converted into useful work. A declining power factor can indicate inefficiencies, aging equipment, and/or potential motor failures. The electrical data can include total harmonic distortion (THD). Harmonic distortions in voltage or current can indicate issues such as improper loads or electrical interference. The electrical data can include voltage imbalance in a three-phase system, which can lead to overheating, inefficiencies, and/or motor damage. The electrical data can include current imbalance in a three-phase system, which can indicate unbalanced loads and/or faulty components. The electrical data can include neutral current monitoring, which can identify unexpected currents on a neutral wire. These currents can indicate grounding issues or unbalanced phase loads. Disclosed implementations may record other electrical data instead of, or in addition to, the aforementioned electrical data. Other data such as vibration data, humidity data, temperature data, and so on can be recorded. The recording can occur at a sampling frequency, which can be different from the uploading frequency. The sampling frequency can occur at a fast enough rate to monitor changes in voltage, current, etc. For example, the sampling frequency can be 20 KHz, 40 HKz, 1 MHz, or another appropriate sampling rate. Because the sampling frequency can be faster than the uploading frequency, the IIEM can store data locally before sending it to the cloud server.

The flow 100 includes determining, by the IIEM, whether the electrical data that was recorded represents a situation of interest 130 related to the one or more industrial devices, wherein the determining is based on the one or more uploading instructions. The determining of the situation of interest can be based on received uploading instructions. A situation of interest can refer to an anomaly or event that may indicate a potential problem, future problem, unusual condition that warrants further investigation, and so on. The situation of interest can be related to power monitoring. A situation of interest can include frequent voltage fluctuations. Voltage swings beyond normal operating range may indicate grid instability, improper load balancing, failing transformers, etc. A situation of interest can include current spikes during equipment startup. While some inrush current is expected during equipment startup, unusually high or prolonged spikes could signal motor aging or increased mechanical resistance. A situation of interest can include phase imbalance in three-phase power. A difference in voltage or current across phases may suggest uneven loads, faulty wiring, or degraded equipment. A situation of interest can include harmonic distortions above a threshold. High total harmonic distortion (THD) can degrade power quality, leading to overheating and inefficiencies. A situation of interest can include unexpected load drops. A sudden decrease in power consumption could indicate an unplanned equipment shutdown, warranting an inspection of the equipment. A situation of interest can include unusual neutral current behavior. A rise in neutral current could point to grounding issues or improper load balancing. Identifying one or more situations of interest can be key to maintaining uptime of industrial equipment. For example, to protect and debug equipment, a user can be notified to react to a situation of interest by briefly taking a machine offline, examining sensitive parts for failure or signs of fatigue, scheduling a maintenance interval, increasing the IIEM uploading frequency to look for additional failure signatures, and so on.

The situation of interest can be related to environmental monitoring. In this case, a situation of interest can also be an indicator of a future equipment failure, allowing the user to address an environmental issue before a stoppage occurs. A situation of interest can include a rapid temperature rise in electrical cabinets. This can be indicative of conditions such as an overloaded circuit, insulation failure, blocked ventilation, etc. A situation of interest can include humidity spikes. A sudden increase in humidity could lead to condensation, corrosion, and electrical shorts. A situation of interest can include a sudden change in ambient temperature in a manufacturing or storage facility. For climate-sensitive applications, this can indicate a possible HVAC system malfunction. A situation of interest can include increased vibration in rotating machinery. A gradual or sudden increase in vibration levels could be a sign of misalignment, bearing failure, imbalance, etc. A situation of interest can include repeated patterns of vibration spikes in a conveyor system. This may indicate an issue with load distribution, roller wear, chain misalignment, and so on. A situation of interest can include seismic activity detected near industrial infrastructure. The aforementioned situations of interest are non-limiting examples, and other situations of interest may be defined in disclosed implementations.

The determining is based on the one or more uploading instructions. As previously described, the uploading instructions can control how and when the IIEM sends data to a cloud server once collected. Previous failure histories, including equipment and/or components that failed, voltage and current signatures, timestamps, location information, and so on can be saved and used to modify uploading instructions. The uploading instructions can be based on a historical database of equipment failures and/or electrical monitoring; a machine learning model, such as a large language model (LLM), which can analyze a historical database or other data; or other methods of predicting failure modes of electrical equipment. Thus, the uploading instructions can include patterns, voltages, currents, thresholds, rates, and so on which, if recorded by the IIEM, can cause the IIEM to identify the conditions as a situation of interest, send the collected data to the cloud server, and/or change the uploading frequency. In response, the cloud server can perform additional analysis, modify and download new uploading instructions to the IIEM, notify a user, send an alert, and so on.

In some embodiments, the uploading instructions are based on a previous failure history of the one or more industrial devices. In other embodiments, the uploading instructions are based on a failure history of the one or more environments. In a usage example, industrial equipment A could have failed in the past when a transient of a certain magnitude and length of time occurred. Thus, the cloud server can update the uploading instructions such that an IIEM coupled to industrial equipment A should immediately upload data when the same transient signature is observed on the same piece of equipment. The IIEM can treat an observation such as this as high priority since a previous failure occurred under the same parameters. As such, the HEM can also send an alert, message, text, and so on. Other IIEMs coupled to other industrial equipment may also upload the data when the same transient signature is noted, according to different uploading instructions. The other IIEMS may associate the data with a lower priority if a previous failure was not detected on the second piece of equipment.

The flow 100 includes uploading, by the IIEM, to the cloud server 140, the electrical data, wherein the uploading is based on the determining. The cloud server can include a bare metal server, with no virtualization, for maximum performance and low latency. The cloud server can include a virtualized server running on top of a hypervisor (e.g., VMware, KVM, Hyper-V). The cloud server can include containerized servers. The containerized servers can be orchestrated via an orchestration system such as Kubernetes. Disclosed implementations may further include load balancing, either as part of the orchestration system, or via dedicated load balancing hardware.

The uploaded electrical data can include voltage, current, waveforms, thresholds, humidity, temperature, and vibration data, etc. In embodiments, the uploading includes one or more portions of the electrical data surrounding the situation of interest. When the uploading instructions direct an IEM to upload electrical data associated with a situation of interest, the IIEM can send data prior to the situation of interest and/or afterward. This can be helpful in diagnosing failures and/or potential failures.

Embodiments include performing local analysis 142, by the IIEM, on the electrical data that was recorded, wherein the performing is based on the uploading frequency, and wherein the uploading includes the local analysis. The local analysis can be performed by the IIEM. The local analysis can include an edge computing or hybrid cloud paradigm, in which some compute power is located closer to users/devices instead of relying on centralized cloud data centers. This paradigm can reduce latency, as well as conserve network bandwidth, by only sending filtered, processed, and/or summarized data to the cloud server. In disclosed implementations, the IIEM can include one or more neural processing units (NPUs). Neural processing units (NPUs) can enable acceleration of artificial intelligence (AI) and machine learning (ML) workloads, particularly for deep learning inference tasks. In disclosed implementations, the NPUs are optimized for matrix operations, tensor computations, and parallel processing, making them well suited for neural network inference on an edge device. In disclosed implementations, the local analysis can supplement analysis by the cloud server. The local analysis can include signal filtering. The signal filtering can include low-pass filtering to remove high-frequency noise while preserving useful signal components. The signal filtering can include high-pass filtering such as filtering to reduce low-frequency drift of DC bias. The signal filtering can include band-pass filtering to isolate a specific frequency range, such as power system harmonics. The local analysis can include frequency domain analysis.

In embodiments, the local analysis includes a fast Fourier transform (FFT). An FFT can convert a signal in the time domain to the frequency domain, where frequency components within a voltage or current waveform can be analyzed. This can be useful for evaluating harmonics which can indicate errors in the equipment monitored, the power supply, and so on. The local analysis can include other transforms such as a short-time Fourier transform (STFT), wavelet transform, and/or other frequency domain operations. The local analysis can include statistical analysis. The statistical analysis can include computation of mean, variance, skewness, and/or kurtosis, to characterize the distribution of signal fluctuations. The statistical analysis can include computation of histograms of amplitudes, to obtain information on how often certain voltage/current values occur. The statistical analysis can include computation of power spectral density (PSD), to measure how signal power is distributed over frequency components. The local analysis can include peak and event detection. The peak and event detection can include detection of voltage and/or current spikes, RMS (root mean square) calculations, zero-crossing rate, and/or other relevant calculations. By performing preprocessing at the edge, disclosed implementations can filter noise, extract important features, detect anomalies, and reduce data volume before sending data to the cloud. This can not only conserve bandwidth, but also improves real-time monitoring and diagnostics.

Embodiments include analyzing, by the cloud server, the electrical data 150 that was uploaded. As described above, the cloud server can also be capable of time-domain analysis, frequency-domain analysis, statistical analysis, and so on. The cloud server analysis can supplement the local analysis. In some implementations, an IIEM may not have the compute resources to perform needed analysis in a timely manner, thus the cloud server can perform the analysis on uploaded data. The analyzing can include comparing the data that was uploaded to a failure history. The comparing can include a machine learning model such as an LLM, neural network, and so on.

In embodiments, the analyzing includes confirming that the electrical data is representative of continuous sampling 160 of the electrical data. Ensuring that the collected electrical data is continuous and free of significant gaps is crucial for accurate analysis, monitoring, and problem detection. In one or more implementations, the IIEM includes a timestamp with each sample. The cloud server can then compare time intervals between successive samples to detect missing data points. Additionally, a sampling rate check can be performed. For example, if data is expected every millisecond but a gap of five milliseconds appears, disclosed implementations may detect that as a data dropout. The confirming can utilize value-based techniques. For example, if an electrical signal is indicated as jumping from 100V to 0V instantly, it may indicate missing data. Moreover, a long sequence of identical values (e.g., zeros or a fixed voltage) may indicate sensor failure or communication issues. The confirming can include sequence validation. The sequence validation can include a rolling window analysis and/or a checksum validation. In disclosed implementations, each data packet sent by the IIEM has a sequence number associated with it. If a packet is dropped, the cloud server can determine that data was dropped, and also how much data was dropped. In response to detecting missing data, disclosed implementations can utilize linear interpolation, spline interpolation, polynomial interpolation, Kalman filtering, and/or another suitable technique to approximate missing data. Other implementations may employ multiple IoT nodes per industrial device, to enable redundancy if one sensor momentarily goes offline or fails. In embodiments, the analyzing includes confirming that the electrical data is representative of continuous sampling of the electrical data.

In embodiments, the confirming is based on one or more heuristics. For example, an uploading instruction to an IIEM can cause the IIEM to send data every minute to the cloud server. If numerous errors, warnings, etc. are produced via the uploaded data, the cloud server can reduce the uploading frequency within a new uploading instruction which can be pushed to the IIEM. This process can continue until the error rate is within a reasonable amount that can be analyzed and acted upon. The reasonable amount can be established heuristically based on processing speed, resources available, type and severity of the errors/warnings, and so on. In some embodiments, the confirming is based on a machine learning model. A machine learning model, such as an LLM, can be used to check if a data pattern that was associated with a past failure was overlooked, not reported in a timely manner, etc. For example, a data pattern, such as a voltage transient over a threshold length and voltage, can be associated with a previous equipment failure. However, when a similar voltage transient is captured by the IIEM, data may not be uploaded immediately, based on the uploading instructions previously described (e.g., the situation may not be recognized as a situation of interest). The machine learning model can find similarities between the data collected by the IIEM and one or more previous failures and can update uploading instructions accordingly so that specific failure modes are not missed, delayed, etc. in the future.

In exemplary implementations, in response to detecting a situation of interest that may be indicative of a dangerous condition, embodiments include shutting down 164 the one or more industrial devices. In one or more implementations, the shutdown can be performed by the cloud server sending a message to the IIEM to send a message to an industrial device to shut down. Alternatively, the cloud server can send a message to the IIEM to send a message to a network-controlled power switch to stop power to one or more industrial devices. In this way, disclosed implementations can automatically shut down industrial devices in response to detecting a situation of interest. This can avoid a larger problem in the future. The flow 100 can further include sending a notification 166. In disclosed implementations, the notification can be sent by the cloud server or IIEM in response to detecting a situation of interest. The notification can include an email, text message, automated telephone call, and/or a notification sent via other messaging applications. The notification can include a date, time, error code, location identifier, equipment identifier, and/or other information. The other information can include parameter values that triggered the notification, such as a temperature reading that exceeded a threshold, a number of current spikes detected within a duration, and so on. The notification can be sent to a user, supervisor, manager, remote monitoring service, etc.

The flow 100 can further include adjusting, by the cloud server, the uploading instructions 170, wherein the adjusting is based on the analyzing. As described above and throughout, the uploading instructions can be adjusted by the cloud server and pushed down to one or more IIEMs which monitor the equipment. The adjusting can include increasing or decreasing an upload frequency. As an example, if previously detected voltage spikes caused the upload frequency to increase, and the voltage spikes have abated for a duration (e.g., the past hour), then an upload frequency can be returned to a default level. Conversely, if voltage spikes are newly being detected, the upload frequency can be increased to obtain more information regarding the power supply condition. The adjusting can also include adding and/or deleting heuristic rules, based on changing conditions. For example, if industrial devices are being taken offline or shut down for maintenance, the upload frequency can be reduced, and monitoring of operating conditions for the industrial device that is getting shut down can be suspended. Other approaches to adjusting upload instructions are possible in disclosed implementations. By monitoring the aforementioned electrical data using disclosed implementations, industrial facilities can enhance predictive maintenance, reduce downtime, and improve energy efficiency, ultimately leading to cost savings and improved equipment lifespan. In embodiments, the confirming is based on one or more heuristics.

Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors.

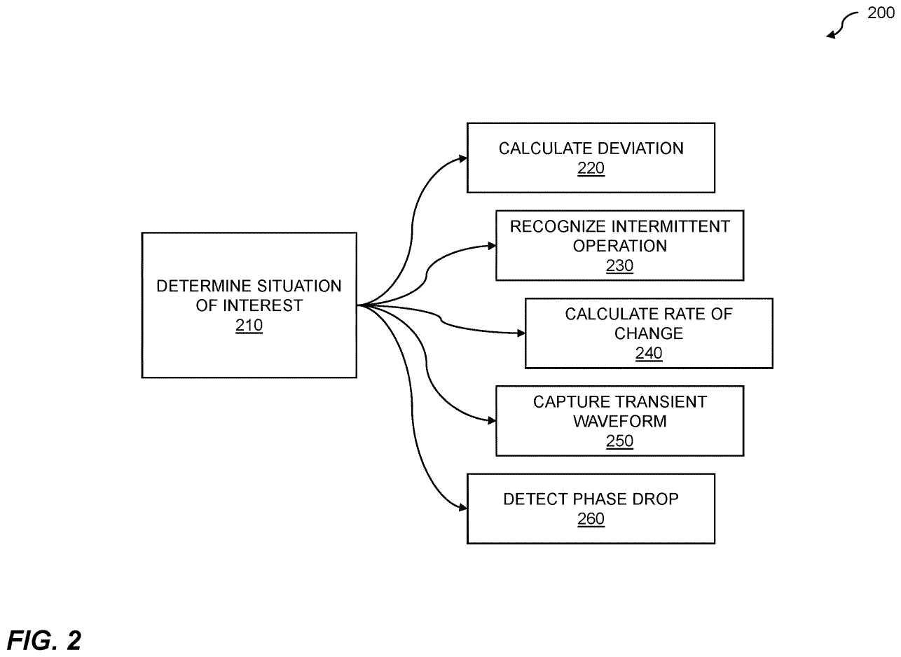

FIG. 2 is a flow diagram for determining a situation of interest. A situation of interest, such as an electrical or environmental condition that can lead to an industrial equipment failure, can enable continuous capture of electrical signatures with IoT-enabled monitors. An industrial IoT electrical monitor (IIEM) is accessed. The HEM is coupled to one or more industrial devices within one or more environments. The HEM receives one or more uploading instructions from a cloud server. Electrical data associated with one or more industrial devices is recorded by the HEM. The HEM determines whether the electrical data that was recorded represents a situation of interest which is related to the one or more industrial devices. The determining is based on the one or more uploading instructions. The HEM uploads the electrical data to a cloud server, based on the determining.

The flow 200 starts with determining a situation of interest 210. Disclosed implementations can determine a variety of situations of interest. As described throughout, a situation of interest can refer to an anomaly or event that may indicate a potential problem, future problem, unusual condition that warrants further investigation, and so on. Examples of situations of interest can include identifying voltage swings beyond a normal operating range, current spikes during equipment startup, a phase imbalance in three-phase power, harmonic distortions above a threshold, a sudden decrease in power consumption, a rise in neutral current, a humidity level exceeding or falling below a threshold, seismic activity, a vibration level exceeding a threshold, a temperature level exceeding or falling below a threshold, an offline status, and/or other scenarios that could lead to an equipment failure. The determining is based on the one or more uploading instructions. As previously described, the uploading instructions can control how and when the IIEM sends data to a cloud server once collected. The uploading instructions can be based on a historical database of equipment failures and/or electrical monitoring; a machine learning model, such as a large language model (LLM), which can analyze a historical database or other data; or other methods of predicting failure modes of electrical equipment. Thus, the uploading instructions can include patterns, voltages, currents, thresholds, rates, and so on, which, if recorded by the HEM, can cause the HEM to identify the conditions as a situation of interest, immediately send the collected data to the cloud server, change the uploading frequency, etc. In response, the cloud server can perform additional analysis, modify and download new uploading instructions to the IIEM, notify a user, send an alert, and so on.

In embodiments, the determining includes calculating, by the IIEM, a deviation 220 from normal operating conditions of the electrical data. The deviation can include a deviation from an expected power usage pattern; a difference in voltage or current supply; a power transient above a time and/or magnitude threshold; a drop of phase; and so on. These types of unexpected changes can suggest inefficiencies, equipment malfunctions, unauthorized usage, etc. They can also serve as an indicator of a future failure. For example, when three-phase power equipment, such as a motor, experiences a drop on phase, overheating and damage can occur quickly if the situation is not immediately addressed. In embodiments, the situation of interest comprises a difference between the deviation and a historical average, wherein the difference is above a threshold. Historical averages and patterns can be stored in the cloud server and compared against data sent by one or more IIEMs. The historical data can be compared to the uploaded data via heuristic rules, machine learning, human analysis, a combination of the aforementioned approaches, and so on. The historical average can be specific to the equipment being monitored, a group of equipment, an environment, etc. In embodiments, the historical average is based on the one or more industrial devices. In embodiments, the historical average is based on the one or more environments.

The flow 200 can include recognizing intermittent operation 230. In embodiments, the determining includes recognizing intermittent operation of the one or more industrial devices, wherein the situation of interest comprises the intermittent operation. The intermittent operation can include stopping and starting of equipment that is expected to be running continuously, such as a fan, conveyor belt, or the like. The starting and stopping can occur randomly, on a schedule, etc. Starting or stopping equipment can introduce power transients on power supplies that also feed other equipment. Thus, the recognizing can occur anytime the equipment starts or stops in order to send data to the cloud server when these actions are detected and determined to be a situation of interest.

The flow 200 can include calculating a rate of change 240. In embodiments, the determining includes calculating a rate of change in one or more elements within the electrical data. The rate of change can include a rate of change in situations of interest. For example, the rate of change can include a rate of change in voltage spikes per ten-minute period. The rate of change can include a rate of change of an environmental parameter, such as a rate of change in temperature, humidity, noise level, vibration, airflow, and so on. In embodiments, the rate of change exceeds a rate threshold. The rate threshold can be determined heuristically, by machine learning, by a human, etc. The rate threshold can be different for different failure modes, industrial equipment, environments, etc. The rate threshold can represent a tolerable rate of a specific failure before action should be taken to reduce the probability of failure of the industrial equipment. For example, a small voltage spike may be tolerable and thus the rate threshold may be high. However, other failures, such as a phase drop, may not be as forgiving and may require immediate action. Thus, the rate threshold may be different for different situations of interest.

In embodiments, the determining includes capturing a transient waveform 250. In some embodiments, the transient waveform comprises a voltage transient. A voltage transient can comprise a deviation from an expected voltage over time. In other embodiments, the transient waveform comprises a current transient. Similar to a voltage transient, a current transient can comprise a deviation from an expected current over time. The transient waveform can include other waveforms detected by a signal that is read by the IIEM. A peak magnitude of the transient waveform can be determined and compared to a transient magnitude threshold by the IIEM. Similarly, a length of the transient waveform can be determined and compared to a transient length threshold by the IIEM. Comparison to these or other thresholds can cause the IIEM to identify the transient as a situation of interest and to trigger the sending of data to the cloud server. The thresholds can be based on a failure mode, a specific piece of industrial equipment, a location on a manufacturing floor, a source of power, an environment, and so on. In some embodiments, the situation of interest comprises a peak magnitude of the transient waveform, wherein an absolute value of the peak magnitude exceeds a transient magnitude threshold. In other embodiments, the situation of interest comprises a length of the transient waveform, wherein the length exceeds a transient length threshold.

The flow 200 can include detecting a phase drop 260. In embodiments, the one or more industrial devices are powered by three-phase power. Many industrial machines, such as motors, compressors, pumps, CNC machines, robotic arms, and HVAC systems, depend on a balanced three-phase power supply for proper operation. Three-phase power can be a more efficient type of AC power used in industrial applications. Each phase represents an AC signal which is separated by 120 degrees. In embodiments, the determining includes detecting a phase drop, wherein the situation of interest comprises the phase drop. A phase drop (e.g., a single-phase loss) in a three-phase power system can occur when one of the three voltage phases fails or significantly decreases while the other two phases remain active. This can happen due to issues such as a blown fuse or tripped breaker in one phase, loose or damaged wiring in one phase, a transformer failure, unbalanced loads that cause excessive current draw in one phase, and many other possible causes. A phase drop can cause serious damage and operational issues, such as overheating, motor damage, torque loss, and/or performance degradation. The HEM can send data to the cloud server when a phase drop is detected. In disclosed implementations, industrial devices can be automatically shut down in response to detecting a phase drop for the power supply that is feeding the industrial devices.

Various steps in the flow 200 may be changed in order, repeated, omitted, or the like without departing from the disclosed concepts. Various embodiments of the flow 200 can be included in a computer program product embodied in a non-transitory computer readable medium that includes code executable by one or more processors.

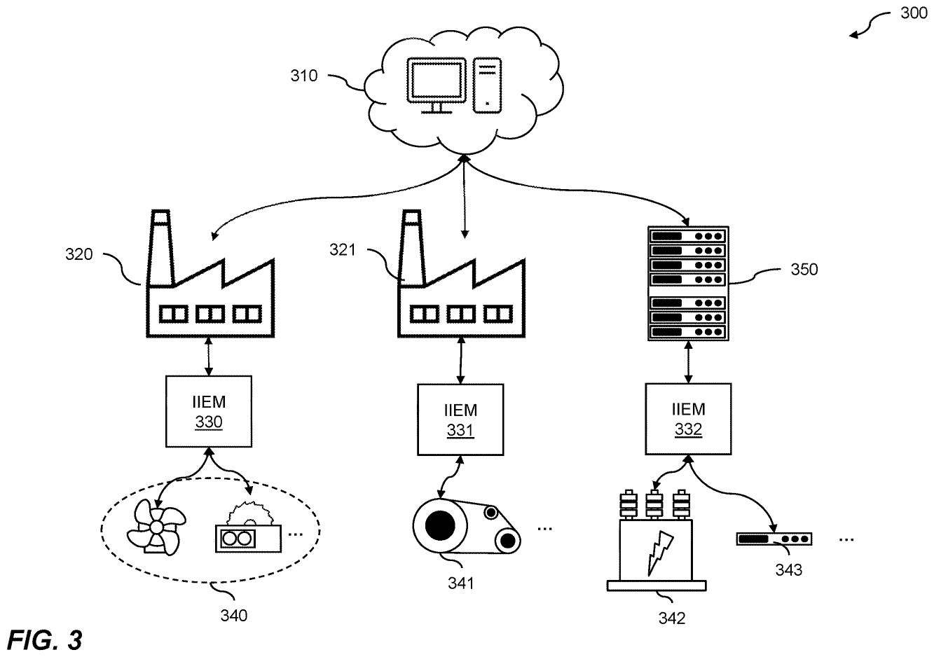

FIG. 3 is an infographic for IoT environments. An IoT environment can enable techniques for equipment monitoring. The Internet of Things (IoT) can refer to a network of interconnected devices that can exchange information over a network such as the Internet, a mobile network such as 5G or long-term evolution (LTE), a private network, short-range communication networks such as Bluetooth, and so on. The devices can include any function for which communication is desired. For example, IoT devices can be used in securing a home with devices such as security cameras, smart thermostats, smart door locks, kitchen appliances, smoke detectors, and so on. These devices can communicate with other devices, systems, networks, etc. to report status, an error, an alert, and so on. Software such as a web application or mobile application can accumulate data from IoT devices and show status, connectivity, battery power, live information, warnings, etc. associated with the devices. Many other applications of IoT devices are possible, such as fitness trackers, smart cars, smart lighting, smart appliances such as ovens and refrigerators, smart plugs and outlets, and so on. The Industrial IoT is an extension of IoT for industrial devices to monitor function, environment, behavior, etc. of machines within industrial environments such as data centers, manufacturing facilities, power plants, wastewater treatment facilities, and many others. The devices can comprise sensors, instruments, machines, etc. that can exchange real-time data about the conditions of one or more machines within the environment, report problems, take actions (such as shutting off a machine), and so on. Such devices can include temperature sensors, pressure sensors, vibration sensors, flow sensors, actuators, monitors, programmable logic controllers (PLCs), and many more.

As discussed above and throughout, an industrial IoT electrical monitor (IIEM) is accessed. The HEM can be coupled to one or more industrial devices within one or more environments. The HEM can detect and record any operating condition of electrical equipment such as voltage, current, humidity, temperature, vibration, and so on. The HEM can receive one or more uploading instructions from a cloud server. The one or more uploading instructions can detail how and when the HEM should upload electrical data to a cloud server. The HEM can use different instructions for each coupled piece of electrical equipment. Electrical data associated with one or more industrial devices is recorded by the HEM. The HEM can determine whether the electrical data that was recorded represents a situation of interest which is related to the one or more industrial devices. The determining can be based on the one or more uploading instructions. The HEM can upload the electrical data to a cloud server, based on the determining. The HEM can analyze, summarize, etc. the electrical data prior to the uploading.

The infographic 300 includes a cloud server 310. In disclosed implementations, the cloud server 310 can be implemented as a bare metal server, one or more containerized instances, and/or one or more virtual machines. The cloud server can include a server in a cloud service such as Amazon Web Services (AWS), a custom managed server, a local (e.g., on-site server, computer, and so on), etc. The cloud server can include any number of physical servers within a rack, data center, network, and so on. The cloud server can include any type of processor, ASIC, SoC, AI accelerator, etc. Load balancing and/or orchestration can be used to enable scaling of cloud server capabilities as the number of industrial devices being monitored increases. The cloud server can communicate with one or more ITEM devices located in various environments, such as facilities and/or locations which house equipment. The cloud server can communicate with the one or more IIEM devices via the Internet, cellular networks, satellite networks, and/or other suitable communication techniques. The IIEM can comprise an IoT node.

As shown in infographic 300, a first IIEM 330 is installed within a first environment 320, a second IIEM 331 is installed within a second environment 321, and a third IIEM 332 is installed within a third environment 350. The first and second environments are shown as manufacturing facilities, and the third environment is shown as a data center. In practice, any environment can be monitored by the IIEM. For example, the equipment can be located in a room within a food processing facility, a rack within a data center, a floor within a manufacturing facility, outdoors, and so on. Any number of IIEMs can be coupled to any number of industrial devices in any number of environments. In a usage example, a single HEM can be coupled to a bandsaw and a table saw within a wood shop. In the infographic 300, ITEM 330 monitors two industrial devices 340, a fan and a table saw, within environment 320. IIEM 331 monitors a single belt drive 341 within environment 321. IIEM 332 monitors generator 342 and computing equipment 343 within environment 350, a data center.

Environment (or facility) 320, environment (or facility) 321, and environment (or data center) 350 can be located in different geographical regions or similar regions. The industrial devices can include elevators, centrifuges, saws, drills, conveyor belts, CNC machines, 3D printers, welding machines, injection molding machines, robotic arms, packaging equipment, sorting machines, uninterruptible power supplies, generators, power transformers, industrial circuit breakers, power distribution units, industrial HVAC systems, furnaces, boilers, refrigeration units, dehumidifiers and humidifiers, pumps, compressors, mixing tanks, water treatment systems, data center computer servers, network switches, load balancers, routers, and/or other types of industrial devices. The IIEMs shown in infographic 300 can capture data from the industrial equipment, and can analyze, summarize, and/or send the data to the cloud server. The IIEMs can be instrumental in recognizing and preventing industrial equipment failures.

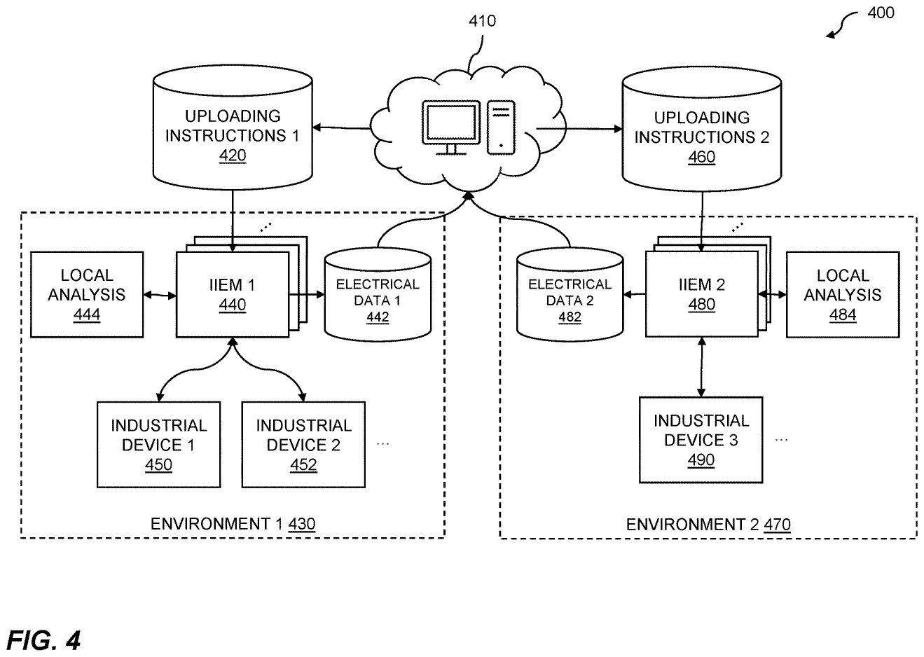

FIG. 4 is a block diagram for continuous capture of electrical signatures with IoT-enabled monitors. The block diagram 400 includes a cloud server 410. Similar to cloud server 310 described previously, cloud server 410 can be implemented as a bare metal server, one or more containerized instances, and/or one or more virtual machines. The cloud server can include a server in a cloud service such as Amazon Web Services (AWS), a custom managed server, a local server (e.g., on-site server, computer, and so on), etc. The cloud server can include any number of physical servers within a rack, data center, network, and so on. The cloud server can include any type of processor, ASIC, SoC, AI accelerator, etc. Load balancing and/or orchestration can be used to enable scaling of cloud server capabilities as the number of industrial devices being monitored increases.

The cloud server can communicate with one or more IIEM devices located at various facilities and/or locations. The cloud server can communicate with the one or more IIEM devices via the Internet, cellular networks, satellite networks, and/or other suitable communication techniques. The cloud server can send one or more sets of uploading instructions to the one or more IIEMs. As shown in block diagram 400, a first set of uploading instructions 420 is sent to a first HEM 440 within a first environment 430. Similarly, a second set of uploading instructions 460 is sent to a second ITEM 480 within a second environment 470. In disclosed implementations, each IIEM can be sent its own set of uploading instructions. Each IIEM can be sent multiple uploading instructions. Each industrial tool coupled to the IIEM can be controlled via its own set of uploading instructions. While two environments are shown in block diagram 400, in practice, there can be more or fewer environments. The environments can represent different facilities, different sections within the same facility, and so on.

Referring now to IIEM 440, it is configured to monitor industrial device 1 450, and industrial device 2 452. Any number of industrial devices can be associated with an IIEM. The IIEM can receive any number of uploading instructions. Each industrial device can be associated with a different uploading instruction or uploading instructions can be shared between one or more industrial devices coupled to the IIEM. In embodiments, a first uploading instruction within the one or more uploading instructions is associated with a first industrial device within the one or more industrial devices, and a second uploading instruction within the one or more uploading instructions is associated with a second industrial device within the one or more industrial devices. The uploading instructions can specify an uploading frequency. In embodiments, an uploading frequency of the first uploading instruction is different from an uploading frequency of the second uploading instruction. In disclosed implementations, the industrial devices may send data directly to the ITEM 440. The data that is collected can include electrical data, environmental data, etc. The electrical data can include voltage, current, transient waveforms, and so on. The environmental data can include data such as airflow, temperature, humidity, and so on. The data collected can be sent to the cloud server according to one or more uploading instructions 420, 460. In embodiments, the one or more uploading instructions include an uploading frequency, wherein the uploading is based on the uploading frequency. The uploading instructions can define one or more situations of interest, as previously described. When the IIEM detects that data collected corresponds to one of the situations of interest, the HEM can send data to the cloud server, regardless of the uploading frequency. The cloud server can send a new set of uploading instructions at any time to any IIEM. The new uploading instructions can cause the HEM to send data more or less frequently, define additional or different situations of interest, remove one or more situations of interest, direct the IIEM to perform local analysis, and so on.

Each HEM 440, 480 may perform local analysis 444. Embodiments include performing local analysis, by the IEM, on the electrical data that was recorded, wherein the performing is based on the uploading frequency, and wherein the uploading includes the local analysis. The local analysis can include signal filtering. The local analysis can include frequency domain analysis. In embodiments, the local analysis includes a fast Fourier transform (FFT). The local analysis can include a Short-Time Fourier Transform (STFT), Wavelet Transform, and/or other frequency domain operations. The local analysis can include statistical analysis. By handling preprocessing locally, the disclosed implementations can minimize noise, highlight key features, identify anomalies, and reduce data size before transmission to the cloud. This approach can conserve network bandwidth and streamline cloud server operations while improving real-time monitoring and diagnostics capabilities. The ITEM 440 collects electrical data 442 from industrial device 1 450 and industrial device 2 452, within environment 1 430. The electrical data 442 is uploaded to the cloud server according to uploading instructions 1 420, for further analysis. Similarly, IIEM 480 collects electrical data 482 from industrial device 3 490 within environment 2 470. The IIEM 480 can perform local analysis 484, similar to that described previously. The electrical data 482 is uploaded to the cloud server according to uploading instructions 2 460 for further analysis. In embodiments, the uploading instructions are based on a failure history of the one or more environments.

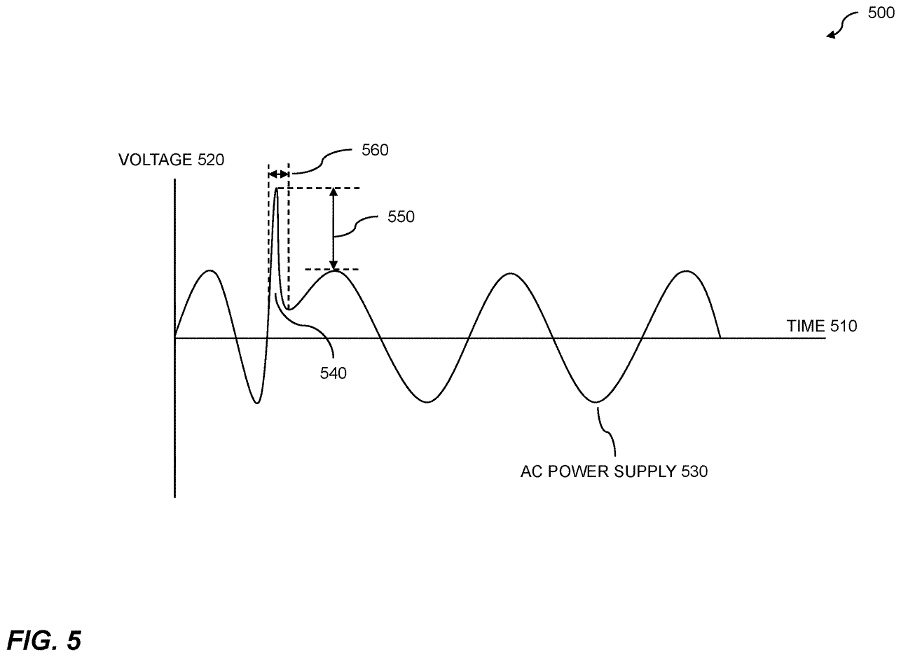

FIG. 5 is an example of a voltage transient. The example 500 includes a horizontal axis 510 representing time, and a vertical axis 520 representing voltage magnitude. Signal 530 represents a monitored alternating current voltage. A transient 540 has a peak amplitude above the normal maximum, indicated at 550, and a peak duration, indicated at 560. In disclosed implementations, if a transient exceeds a predetermined peak duration and/or peak amplitude above the normal maximum, then the transient can be treated as a situation of interest. The predetermined peak and/or duration can be defined heuristically from previous failures on similar equipment, via machine learning on a historical database, manually by a human, and so on. The cloud server can send updated uploading instructions to any IEM with updated predetermined thresholds such as duration and peak magnitude. Thus, the cloud server can dynamically change the definition of a situation of interest. A similar principle can be applied to electrical current as well as voltage. The number of transients detected within a given time duration can be a situation of interest. Too many transients within a given time duration can be indicative of power grid instability, and/or other adverse conditions. The uploading instruction can include a threshold rate of transients, such as voltage of current transients.

Voltage spikes, current spikes, and/or other transient events on an AC power line can occur when there is a sudden, short-duration increase in voltage or current. These transients can often last from nanoseconds to milliseconds and can cause significant disruptions or damage to electrical systems. There are various contributors to transient events. Direct lightning strikes to power lines can cause massive voltage surges. Even indirect lighting strikes can induce electromagnetic pulses that can travel through power lines and damage equipment. Switching operations in the power grid can also cause transient events. For example, the energization or de-energization of long power lines can cause transient voltages due to the capacitance and inductance of the power grid. Moreover, the starting or stopping of industrial equipment such as motors, compressors, furnaces, and large transformers can cause sudden current draws or dumps, leading to voltage sags, spikes, harmonic distortions, etc. Short circuits and faults can cause sudden shifts in current, which can result in transients. Additionally, if a large facility or region suddenly disconnects from the power grid, the abrupt loss of load can create transient voltage fluctuations. Nonlinear loads (such as rectifiers, variable frequency drives, and power electronics) can introduce harmonics into the power grid. Furthermore, high-power RF sources, such as nearby radio transmitters or industrial RF equipment, can couple energy into power lines, introducing high-frequency transients. Regardless of the cause, these transients can damage sensitive electronics, reduce the lifespan of equipment, and cause operational disruptions. The real-time monitoring of disclosed implementations can help mitigate the impact of transients. In embodiments, the situation of interest comprises a peak magnitude of the transient waveform, wherein an absolute value of the peak magnitude exceeds a transient magnitude threshold. In embodiments, the situation of interest comprises a length of the transient waveform, wherein the length exceeds a transient length threshold. In disclosed implementations, the transient magnitude threshold and/or transient length threshold can be user-defined, and/or initialized to default values that can be adjusted later based on performance of the monitored industrial devices.

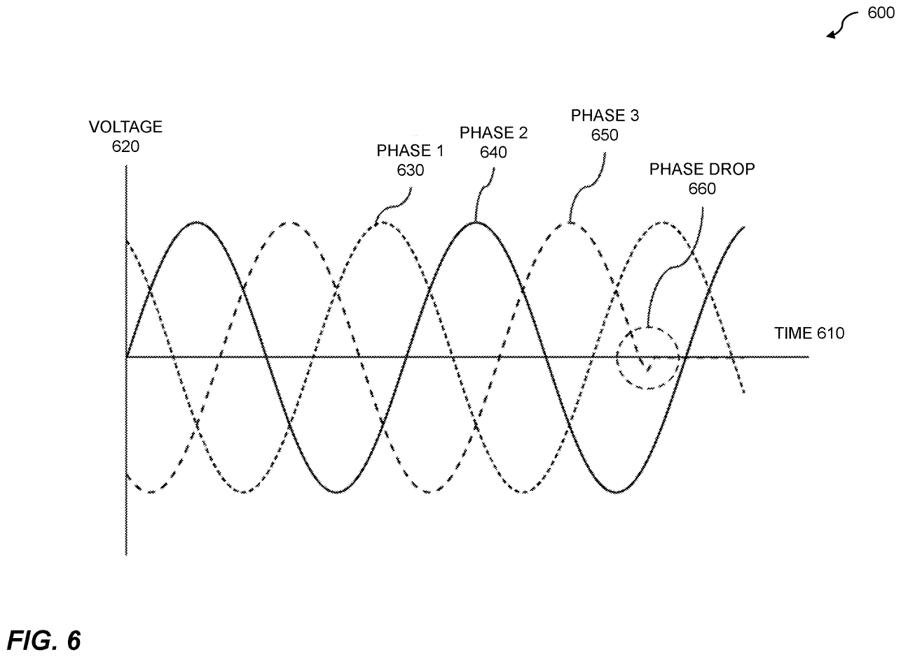

FIG. 6 is an example of a phase drop. The example 600 includes a horizontal axis 610 representing time, and a vertical axis 620 representing voltage magnitude. A first phase 630, a second phase 640, and a third phase 650 are shown. Three-phase power is a type of AC (alternating current) electrical power distribution that includes three sinusoidal voltage waveforms that are evenly spaced in phase. Three-phase power is the most common technique used for transmitting and distributing electrical power in industrial, commercial, and high-power applications because it provides a more balanced and efficient power delivery compared to single-phase systems. In a balanced three-phase system, each voltage waveform has the same frequency and amplitude (e.g., peak voltage). Each phase is 120 degrees out of phase with the other phases. The frequency can typically range from 50 Hertz to 60 Hertz. In disclosed implementations, the three-phase power can be in a wye configuration or a delta configuration. Note that the vertical axis can be a current axis instead, without departing from the disclosed concepts.

A phase drop 660 that is associated with phase 3 is shown in example 600. A phase drop (also known as single-phase loss) in a three-phase power system occurs when one of the three voltage phases fails or experiences a significant drop while the other two remain active. This can result from various issues, including a blown fuse, a tripped breaker, loose or damaged wiring, transformer failure, or unbalanced loads that lead to excessive current draw in a single phase. In embodiments, the one or more industrial devices are powered by three-phase power. Many industrial machines, such as motors, compressors, pumps, CNC machines, robotic arms, and HVAC systems, rely on a stable and balanced three-phase power supply for optimal performance. A phase drop can lead to severe consequences, including overheating, motor damage, torque loss, and overall performance degradation.

Recall that an IIEM can determine whether the electrical data that was recorded represents a situation of interest related to the one or more industrial devices, wherein the determining is based on the one or more uploading instructions. In some embodiments, the determining includes detecting a phase drop, wherein the situation of interest comprises the phase drop. Industrial devices can be automatically shut down upon detecting a phase drop in their power supply to prevent potential damage. In the described implementations, a phase drop can be designated as a situation of interest, causing one or more IIEMs to send electrical data to the cloud server. In response, the cloud server and/or the IEM can warn a user, send an alert, shut down the equipment, and so on.

The detection of a phase drop can include performing a phase-to-neutral voltage check. The detection of a phase drop can include measuring the voltage of each phase relative to neutral (if available). A significant drop or loss in one phase indicates a phase drop. The detection of a phase drop can include performing a phase-to-phase voltage check. This can include comparing voltages between phases. A missing or significantly lower voltage between two phases can signal a phase failure. Some implementations can utilize phase angle monitoring to detect a phase drop. One or more implementations may utilize a phase loss relay to detect missing phases and trigger alerts and/or shutdowns of industrial equipment.

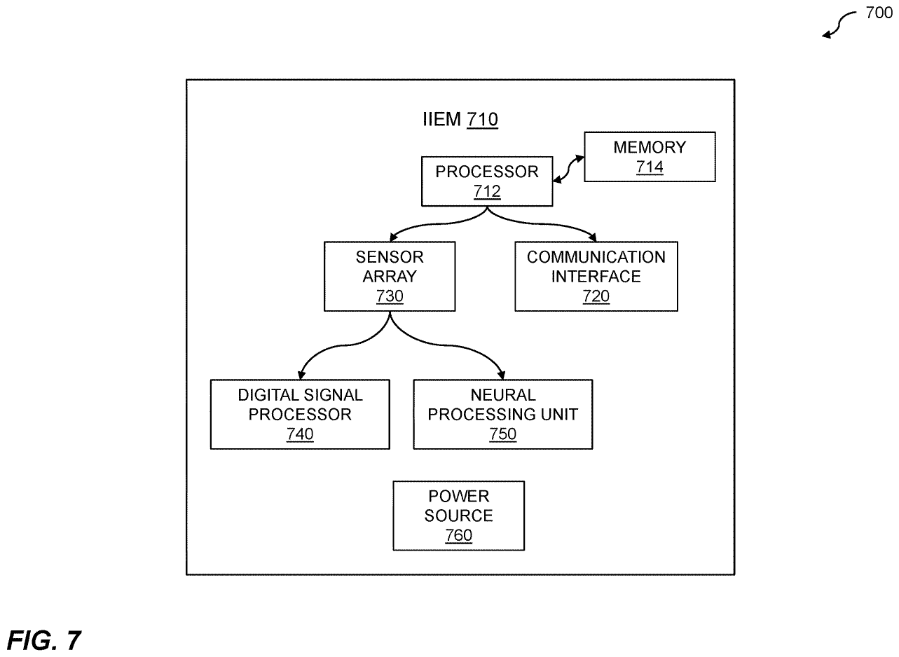

FIG. 7 is a block diagram of an IIEM. In the block diagram 700, ITEM 710 can include a processor 712. The processor can include an ARM®-based processor, MIPS®-based processor, a custom processor, application specific integrated circuits (ASICs), systems-on-chip (SoCs), one or more embedded controllers, a processor within a Rasberry Pi® board, and/or another suitable processor or computer type. The processor can be coupled to memory 714. The memory can include flash memory, read-only memory (ROM), random-access memory (RAM), caches such as coherent caches, hard drives, and/or other suitable storage technologies. The memory can include portions for storing executable instructions which are executed by the processor. The memory can include portions for storing acquired data, logs, intermediate results, and so on.

The IIEM in block diagram 700 can include a communication interface 720. The communication interface can enable communications between the cloud server and the IIEM, between the IIEM and one or more industrial devices, between the ITEM and other IIEMs, and so on. The communication interface can support wired and wireless communications. The communication interface can include wired communication such as ethernet, serial, and/or optical interfaces. The communication interface can include wireless communication such as Wi-Fi, Bluetooth, Bluetooth Low Energy, Zigbee, cellular, satellite, and/or other wireless communication technologies. The communication interface can include cellular communication protocols such as 3G, 4G LTE, 5G, and so on. The communication interface can be responsible for input and output (I/O) functions.

The IEM in block diagram 700 can include a sensor array 730. The sensor array can include one or more sensors. The sensors can include a voltage sensor, current sensor, temperature sensor, humidity sensor, motion sensor, RF energy sensor, vibration sensor, and/or other suitable types of sensors. The data obtained from the sensors can be used to enable continuous capture of electrical signatures with IoT-enabled monitors. The sensor array can include one or more analog outputs, analog inputs, digital outputs, digital inputs for acquiring measurement data, and/or control of measuring equipment and/or industrial devices. The sensor array can support sampling of electrical data associated with one or more industrial devices. The sampling can support a frequency of 20 Hz, 40 KHz, or any other appropriate sampling rate.

The IIEM in block diagram 700 can further include a digital signal processor (DSP) 740. The DSP can enable additional local analysis functionality on signals obtained by one or more sensors in sensor array 730. In disclosed implementations, the DSP can provide filtering functions, such as low-pass filtering, high-pass filtering, band-pass filtering, and/or notch filtering. The DSP can provide frequency and harmonic analysis, such as performing fast Fourier transform (FFT) operations to decompose an AC signal into its frequency components to detect harmonics and distortion. In embodiments, the local analysis includes a fast Fourier transform (FFT). The DSP may also enable a total harmonic distortion (THD) calculation, which can be used to identify excessive harmonics that may degrade power quality. Moreover, the DSP can enable additional transient and event detection, such as voltage spikes and/or current spikes. In disclosed implementations, the DSP may perform continuous waveform comparison, in which waveforms are continuously compared to reference signals in order to detect anomalies. The DSP can also enable phase angle measurements, which are useful for determining phase shifts and power imbalances in three-phase power systems. In addition to AC power analysis, the DSP may further perform DC analysis functions, such as ripples caused by unwanted AC components in DC signals, which can be an indicator of failing rectifiers. Disclosed implementations may include other functions performed by the DSP. In some implementations, where a DSP is not provided within the IIEM, the above calculations can be accomplished with the processor, however, these functions may execute more slowly.

The IEM in block diagram 700 can further include a neural processing unit (NPU) 750. The NPU can enable additional local analysis. The NPU can enable acceleration of machine learning (ML) and deep learning (DL) tasks. The NPU may include hardware elements such as matrix multiplication units (MMUs) to accelerate tensor-based computations, which are fundamental in deep learning models. Additionally, the NPU may include activation function units to process non-linear activation functions, such as ReLU, Sigmoid, and Tanh, more efficiently than a general-purpose processor. The NPU may further include convolution engines to support convolutional neural networks (CNNs) that can be well suited for pattern recognition tasks. In disclosed implementations, electrical data, such as voltage fluctuations, current spikes, harmonics, power factor shifts, and/or phase imbalances in an AC power system, can be provided to the NPU. Moreover, environmental conditions, such as temperature, humidity, vibration, and/or air quality, can be provided to the NPU. The NPU can be configured to analyze historical data to recognize patterns that might predict failures before they occur. As an example, the NPU can be configured to use recurrent neural networks (RNNs) and/or transformer-based models to detect long-term trends. The NPU can utilize models to perform statistical anomaly detection to identify deviations from default conditions. In embodiments, the determining includes calculating, by the IIEM, a deviation from normal operating conditions of the electrical data. In some embodiments, the confirming is based on one or more heuristics. In other embodiments, the confirming is based on a machine learning model. In disclosed implementations, the NPU may process machine learning models that correlate power/environmental anomalies with past failures, enabling proactive maintenance. Performing such functions locally, within the environment of the industrial devices, enables quicker detection of potential problems with industrial devices, and also reduces network bandwidth consumption by reducing the amount of data that must be sent to the cloud server. The IIEM can include a power source 760. The power source can include a battery, an external power source, and/or a shared power delivery mechanism, such as power over ethernet.

In some implementations, the IIEM can be distinct from an IoT node. In those cases, one or more IIEMs within an environment can be coupled to one or more industrial devices. The one or more IIEMs can send data to the IoT device which can coordinate sending and receiving data with a server, cloud server, etc. The IoT device can include one or more processors, communication interfaces, and so on. The IIEM can communicate with the IoT node via Bluetooth, cellular communications, and so on. In some cases, one or more IoT nodes may include an ethernet port, serial port, and/or other port that supports wired communication.

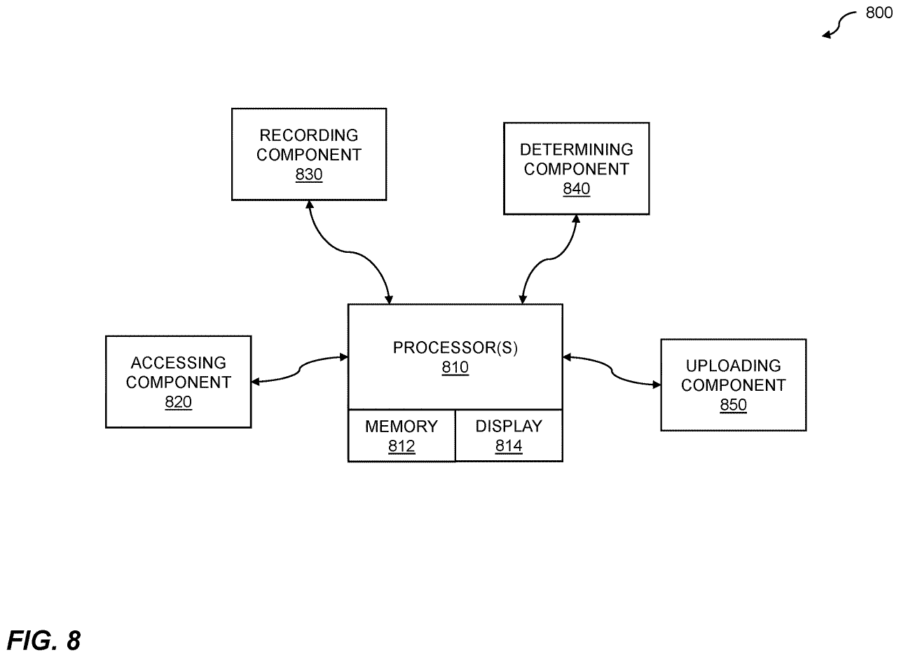

FIG. 8 is a system diagram for continuous capture of electrical signatures with IoT-enabled monitors. The system 800 can comprise a computer system for implementation of continuous capture of electrical signatures with IoT-enabled monitors. The computer system can be based on semiconductor logic. The system can include one or more of processors, memories, cache memories, queues, displays, communication channels and networks, and so on. The system 800 can include one or more processors 810. The processors can include standalone processors within integrated circuits or chips, processor cores in FPGAs or ASICs, two or more processor cores within a multiprocessor, and the like. The one or more processors 810 are coupled to a memory 812, which can store instructions, operations, network traffic data, data requests, electrical data analysis, heuristics for industrial environments, routing information, and so on. The memory can include one or more of local memory, shared cache memory, shared hierarchical cache memory, system memory such as shared system memory, etc. The system 800 can further include a display 814 coupled to the one or more processors. The display can be used for displaying data, instructions, operations, memory queue contents, various types of latencies, routing information, etc. The operations can include routing operations, data transfer operations, and so on.

The system 800 can include an accessing component 820. The accessing component 820 can include functions and instructions for accessing an industrial IoT electrical monitor (IIEM), wherein the HEM is coupled to one or more industrial devices within one or more environments, and wherein the IIEM receives, from a cloud server, one or more uploading instructions. As previously described, the IIEM can record data from one or more industrial devices and send the data to a cloud server. The recording can be based on a sampling frequency, one or more situations of interest, etc. The sending can be based on the uploading instructions. The cloud server can update the uploading instructions at any time. The accessing can include using one or more application programming interface (API) calls. The accessing can include use of RESTful APIs (HTTP/HTTPS), MQTT (Message Queuing Telemetry Transport), CoAP (Constrained Application Protocol), AMQP (Advanced Message Queuing Protocol), OPC UA (Open Platform Communications Unified Architecture), WebSockets (for Real-Time Monitoring via Web Applications), LoRaWAN (for Remote, Low-Power Monitoring), and/or other suitable protocols.

The system 800 can include a recording component 830. The recording component 830 can include functions and instructions for recording, by the IIEM, electrical data associated with the one or more industrial devices. The electrical data can include voltage data, current data, frequency data, phase data, data regarding transients, three-phase data, DC ripple data, and/or other relevant electrical data. The electrical data can be analyzed before sending to the cloud server. The analysis can be based on an FFT, STFT, wavelet transform, and so on. The system 800 can include a determining component 840. The determining component 840 can include functions and instructions for determining, by the IIEM, whether the electrical data that was recorded represents a situation of interest related to the one or more industrial devices, wherein the determining is based on the one or more uploading instructions. The determining can be based on heuristics, data-driven rules, pattern analysis, machine learning, and so on. In disclosed implementations, trained machine learning models can be used to identify patterns corresponding to a situation of interest. The uploading instructions can cause the IIEM to upload data on an uploading frequency. When a situation of interest is recognized by the IIEM, data can be sent to the cloud server regardless of the uploading frequency.

The system 800 can include an uploading component 850. The uploading component 850 can include functions and instructions for uploading, by the IIEM, to the cloud server, the electrical data, wherein the uploading is based on the determining. In disclosed implementations, the data can be compressed prior to uploading. The uploading may be performed on a schedule. The schedule can be dynamic. The frequency of the uploading can change in response to determining a situation of interest. The data that is uploaded can include data occurring both before and after a situation of interest is determined. As an example, in response to determining a situation of interest, 30 seconds of data prior to the situation of interest, along with 30 seconds of data following the situation of interest, can be uploaded to the cloud server. In embodiments, the uploading includes one or more portions of the electrical data surrounding the situation of interest. In disclosed implementations, only a portion of the data collected by an HEM is uploaded, while another portion of the data collected by an IIEM may be temporarily stored locally and then discarded. In embodiments, the uploading instructions are based on a previous failure history of the one or more industrial devices. For example, industrial devices that have a history of frequent failure may be monitored with a higher uploading frequency than industrial devices that do not have a history of frequent failure.

The system 800 can include a computer program product embodied in a non-transitory computer readable medium for analysis, the computer program product comprising code which causes one or more processors to perform operations of: accessing an industrial IoT electrical monitor (IIEM), wherein the HEM is coupled to one or more industrial devices within one or more environments, and wherein the HEM receives, from a cloud server, one or more uploading instructions; recording, by the HEM, electrical data associated with the one or more industrial devices; determining, by the IIEM, whether the electrical data that was recorded represents a situation of interest related to the one or more industrial devices, wherein the determining is based on the one or more uploading instructions; and uploading, by the IIEM, to the cloud server, the electrical data, wherein the uploading is based on the determining.

The system 800 can include a computer system for analysis comprising: a memory which stores instructions; one or more processors attached to the memory wherein the one or more processors, when executing the instructions which are stored, are configured to: access an industrial IoT electrical monitor (IIEM), wherein the IIEM is coupled to one or more industrial devices within one or more environments, and wherein the IIEM receives, from a cloud server, one or more uploading instructions; record, by the IIEM, electrical data associated with the one or more industrial devices; determine, by the IIEM, whether the electrical data that was recorded represents a situation of interest related to the one or more industrial devices, wherein the determining is based on the one or more uploading instructions; and upload, by the IIEM, to the cloud server, the electrical data, wherein the uploading is based on the determining.

As can now be appreciated, disclosed implementations can provide industrial monitoring that continuously tracks the performance of industrial devices and detects anomalies in the power supply, providing significant benefits in terms of equipment protection, operational efficiency, and cost savings. Industrial devices such as motors, compressors, CNC machines, robotic arms, and HVAC systems rely on a stable power supply to function properly. Power anomalies such as voltage spikes, phase drops, and harmonic distortions can cause serious damage, leading to costly repairs or even permanent equipment failure. Unplanned equipment failures due to poor power conditions can halt production lines, disrupt operations, and lead to significant revenue losses. Disclosed implementations can detect power anomalies early, allowing for proactive maintenance and rapid issue resolution. Thus, disclosed implementations can assist in preventing unexpected failures, reducing downtime, and improving overall safety.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system”—may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for analysis comprising:
accessing an industrial IoT electrical monitor (IIEM), wherein the IIEM is coupled to one or more industrial devices within one or more environments, and wherein the IIEM receives, from a cloud server, one or more uploading instructions;
recording, by the IIEM, electrical data associated with the one or more industrial devices;
determining, by the IIEM, whether the electrical data that was recorded represents a situation of interest related to the one or more industrial devices, wherein the determining is based on the one or more uploading instructions; and
uploading, by the IIEM, to the cloud server, the electrical data, wherein the uploading is based on the determining.

2. The method of claim 1 wherein the one or more uploading instructions include an uploading frequency, wherein the uploading is based on the uploading frequency.

3. The method of claim 2 further comprising performing local analysis, by the HEM, on the electrical data that was recorded, wherein the performing is based on the uploading frequency, and wherein the uploading includes the local analysis.

4. The method of claim 1 wherein the determining includes calculating, by the HEM, a deviation from normal operating conditions of the electrical data.

5. The method of claim 4 wherein the situation of interest comprises a difference between the deviation and a historical average, wherein the difference is above a threshold.

6. The method of claim 5 wherein the historical average is based on the one or more industrial devices.

7. The method of claim 5 wherein the historical average is based on the one or more environments.

8. The method of claim 1 wherein the determining includes recognizing intermittent operation of the one or more industrial devices, wherein the situation of interest comprises the intermittent operation.

9. The method of claim 1 wherein the determining includes calculating a rate of change in one or more elements within the electrical data.

10. The method of claim 9 wherein the rate of change exceeds a rate threshold.

11. The method of claim 1 wherein the determining includes capturing a transient waveform.

12. The method of claim 11 wherein the situation of interest comprises a peak magnitude of the transient waveform, wherein an absolute value of the peak magnitude exceeds a transient magnitude threshold.

13. The method of claim 11 wherein the situation of interest comprises a length of the transient waveform, wherein the length exceeds a transient length threshold.

14. The method of claim 1 wherein the one or more industrial devices are powered by three-phase power.

15. The method of claim 14 wherein the determining includes detecting a phase drop, wherein the situation of interest comprises the phase drop.

16. The method of claim 1 further comprising analyzing, by the cloud server, the electrical data that was uploaded.

17. The method of claim 16 wherein the analyzing includes confirming that the electrical data is representative of continuous sampling of the electrical data.

18. The method of claim 17 further comprising adjusting, by the cloud server, the uploading instructions, wherein the adjusting is based on the analyzing.

19. The method of claim 1 wherein the uploading instructions are based on a previous failure history of the one or more industrial devices.

20. The method of claim 1 wherein the uploading instructions are based on a failure history of the one or more environments.

21. The method of claim 1 wherein the uploading includes one or more portions of the electrical data surrounding the situation of interest.

22. The method of claim 1 wherein a first uploading instruction within the one or more uploading instructions is associated with a first industrial device within the one or more industrial devices, and a second uploading instruction within the one or more uploading instructions is associated with a second industrial device within the one or more industrial devices.

23. The method of claim 22 wherein an uploading frequency of the first uploading instruction is different from an uploading frequency of the second uploading instruction.

24. A computer program product embodied in a non-transitory computer readable medium for analysis, the computer program product comprising code which causes one or more processors to perform operations of:
accessing an industrial IoT electrical monitor (IIEM), wherein the IIEM is coupled to one or more industrial devices within one or more environments, and wherein the IIEM receives, from a cloud server, one or more uploading instructions;
recording, by the IIEM, electrical data associated with the one or more industrial devices;
determining, by the IIEM, whether the electrical data that was recorded represents a situation of interest related to the one or more industrial devices, wherein the determining is based on the one or more uploading instructions; and
uploading, by the IIEM, to the cloud server, the electrical data, wherein the uploading is based on the determining.

25. A computer system for analysis comprising:
a memory which stores instructions;
one or more processors attached to the memory wherein the one or more processors, when executing the instructions which are stored, are configured to:
access an industrial IoT electrical monitor (IIEM), wherein the IIEM is coupled to one or more industrial devices within one or more environments, and wherein the IIEM receives, from a cloud server, one or more uploading instructions;
record, by the IIEM, electrical data associated with the one or more industrial devices;
determine, by the IIEM, whether the electrical data that was recorded represents a situation of interest related to the one or more industrial devices, wherein the determining is based on the one or more uploading instructions; and
upload, by the IIEM, to the cloud server, the electrical data, wherein the uploading is based on the determining.
